(19) United States
(12) Patent Application Publication
(10) Pub. No.: US 2015/0221768 A1
(43) Pub. Date: Aug. 6, 2015

(54) SEMICONDUCTOR STRUCTURE AND METHOD FOR MANUFACTURING THE SAME

(71) Applicant: Institute of Microelectronics, Chinese Academy of Sciences, Beijing (CN)

(72) Inventors: Huicai Zhong, San Jose, CA (US); Qingqing Liang, Lagrangeville, NY (US); Chao Zhao, Kessel-lo (BE); Jun Luo, Beijing (CN)

(21) Appl. No.: 14/423,132

(22) PCT Filed: Sep. 17, 2012
(86) PCT No.: PCT/CN2012/081511

§ 371 Date: Feb. 22, 2015

(30) Foreign Application Priority Data
Aug. 23, 2012 (CN) 201210304223.8

(51) Int. Cl. H01L 29/78; H01L 29/417; H01L 29/40; H01L 29/66

(52) U.S. Cl. CPC H01L 29/7845; H01L 29/7848; H01L 29/66636; H01L 29/4175; H01L 29/401

(57) ABSTRACT

A method of manufacturing a semiconductor structure is disclosed. The method comprises: providing a substrate, forming a gate stack on the substrate and forming source/drain regions within the substrate; etching the source/drain regions to form trenches; forming a contact layer on the surface of the source/drain regions that have been etched; forming a stress material layer within the trenches; depositing an interlayer dielectric layer and forming contact plugs in contact with the stress material. Accordingly, a semiconductor structure is also disclosed. In the present invention, trenches are formed by etching source/drain regions in order to increase exposed areas at the source/drain regions, a contact layer is formed on the surface of the source/drain regions, and a stress material is filled into the trenches, which is capable of reducing effectively contact resistance between the contact layer and source/drain regions while introducing stress into channels, and thereby enhancing carrier mobility and improving performance of semiconductor structures.

The present application claims priority benefit of Chinese patent application No. 201210304223.8, filed on 23 Aug. 2012, entitled “SEMICONDUCTOR STRUCTURE AND METHOD FOR MANUFACTURING THE SAME”, which is herein incorporated by reference in its entirety.

### FIELD OF THE INVENTION

The present invention relates to semiconductor manufacturing technologies, and particularly, to a semiconductor structure and a method for manufacturing the same.

### BACKGROUND OF THE INVENTION

In the prior art, traditional semiconductor structures are manufactured according to a method described as follows (with reference to FIG. 1, which illustrates a cross-sectional view of a semiconductor structure in the prior art): providing a substrate 100 with a gate stack, wherein the gate stack comprises a gate dielectric layer 210, a metal gate 200 and sidewall spacers 240; forming source/drain regions 110 respectively within the substrate 100 on each side of the gate stack; forming a contact layer 111 (e.g. a metal silicide layer) on the surface of the source/drain regions 110; depositing an interlayer dielectric layer 300 to cover the source/drain regions 110 and the gate stack; etching the interlayer dielectric layer 300 till the source/drain regions 110 are exposed so as to form contact holes 310 or contact grooves 310(a); filling a contact metal into the contact holes 310 or contact grooves 310(a) to form hole-shaped contact plugs (as shown in FIG. 1(a), which illustrates a top view of a semiconductor structure with hole-shaped contact plugs of as shown in FIG. 1) or groove-shaped contact plugs (as shown in FIG. 1(b), which illustrates a top view of a semiconductor structure with groove-shaped contact plugs as shown in FIG. 1). Owing to presence of the contact layer 112 between the contact plugs and the source/drain regions 110, contact resistance at the source/drain regions 110 has been reduced favorably.

However, the prior art has proposed to improve performance of semiconductor structures merely by forming a contact layer on the surface of source/drain regions, rather than modifying and improving performance of semiconductor devices by way of further introducing stress into channels on the basis of aforementioned structure.

Accordingly, it becomes urgent to find solutions to such problems as how to reduce contact resistance at source/drain regions at the meantime of introducing stress in channels for purposes of enhancing carrier mobility within channels and thereby further improving performance of semiconductor structures.

### SUMMARY OF THE INVENTION

The present invention is intended to provide a semiconductor structure and a method for manufacturing the same, which are favorable for reducing contact resistance between a contact layer and source/drain regions and further enhancing stress in channels, so as to improve carrier mobility within the channels.

In one aspect, the present invention provides a method for manufacturing a semiconductor structure, which comprises:
a) providing a substrate, forming a gate stack on the substrate and forming source/drain regions within the substrate;
b) etching the source/drain regions to form trenches;
c) forming a contact layer on the surface of the source/drain regions that have been etched;
d) forming a stress material layer within the trenches; and
e) depositing an interlayer dielectric layer and forming contact plugs in contact with the stress material.

In another aspect, the present invention further provides a semiconductor structure comprising a substrate, a gate stack, source/drain regions, a contact layer, an interlayer dielectric layer and contact plugs, wherein:

the gate stack is formed on the substrate;

the source/drain regions are formed respectively within the substrate on each side of the gate stack;

the contact layer is located on a surface of the source/drain regions;

the interlayer dielectric layer covers the source/drain regions and the gate stack;

a stress material layer is embedded into the source/drain regions and is formed on the contact layer; and

the contact plugs are embedded within the interlayer dielectric layer and are electrically connected to the stress material layer.

As compared to the prior art, the present invention has the following advantages.

Trenches are formed by etching source/drain regions, so as to increase the exposed area of the source/drain regions. Then, a contact layer is formed on the surface of the source/drain regions and a stress material is filled into the trenches, which is favorable for reducing effectively contact resistance between the contact layer and the source/drain regions at the meantime of introducing stress into channels, so as to enhance carrier mobility within channels and to improve performance of semiconductor structures.

### BRIEF DESCRIPTION OF THE DRAWINGS

Other additional features, objects and advantages of the present invention are made more evident according to perusal of the following detailed description of exemplary embodiment(s) in conjunction with accompanying drawings:

FIG. 1 illustrates a cross-sectional view of a semiconductor structure in the prior art;

FIG. 1(a) illustrates a top view of a semiconductor structure with hole-shaped contact plugs as shown in FIG. 1;

FIG. 1(b) illustrates a top view of a semiconductor structure with groove-shaped contact plugs as shown in FIG. 1;

FIG. 2 illustrates a diagram of a method for manufacturing a semiconductor structure according to the present invention;

FIG. 3 to FIG. 12 illustrate respectively cross-sectional views of a semiconductor structure manufactured at respective stages according to an embodiment of the method for manufacturing a semiconductor structure as illustrated in FIG. 2; and

FIG. 3(a) to FIG. 12(a) illustrate top views of a semiconductor structure at respective manufacturing stages as shown in FIG. 3 to FIG. 12.

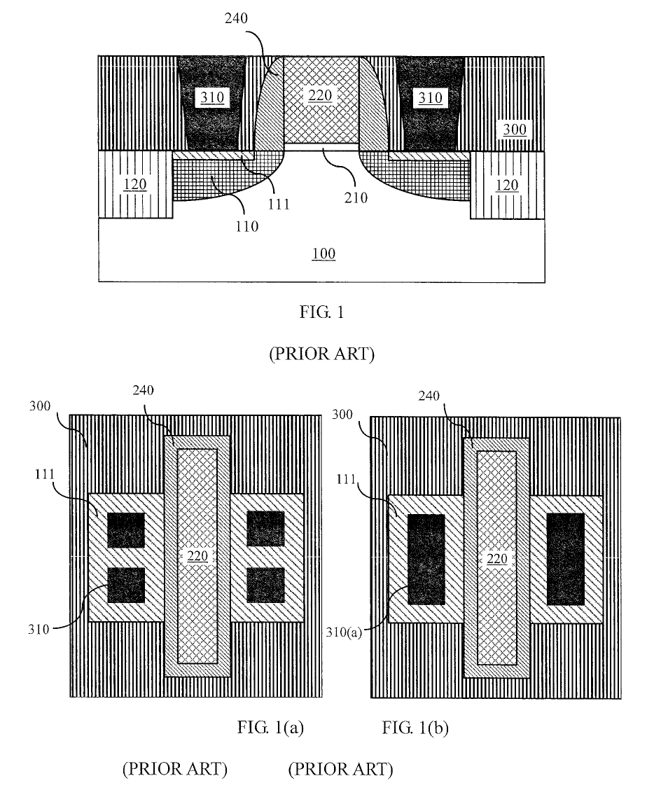

The same or similar reference signs in the drawings denote the same or similar elements.

### DETAILED DESCRIPTION OF THE INVENTION

Embodiments of the present invention are to be described in detail below, wherein examples of embodiments are illustrated in the drawings, in which same or similar reference signs throughout denote same or similar elements or elements having same or similar functions. It should be understood that embodiments described below in conjunction with the drawings are illustrative, and are provided for explaining the present invention only, and thus shall not be interpreted as a limit to the present invention.

Various embodiments or examples are provided here below to implement different structures of the present invention. To simplify the disclosure of the present invention, descriptions of components and arrangements of specific examples are given below. Of course, they are only illustrative and not limiting the present invention. Moreover, in the present invention, reference numbers and/or letters may be repeated in different examples. Such repetition is for purposes of simplicity and clarity, yet does not denote any relationship between respective embodiments and/or arrangements under discussion. Furthermore, the present invention provides various examples for various processes and materials. However, it is obvious for a person of ordinary skill in the art that other processes and/or materials may be alternatively utilized. In addition, following structures where a first feature is “on/above” a second feature may include an embodiment in which the first feature and the second feature are formed to be in direct contact with each other, and may also include an embodiment in which another feature is formed between the first feature and the second feature such that the first and second features might not be in direct contact with each other. However, it should be noted that elements shown in appended drawings might not be drawn to scale. Description of the conventionally known elements, processing techniques and crafts are omitted from description of the present invention in order not to limit the present invention unnecessarily.

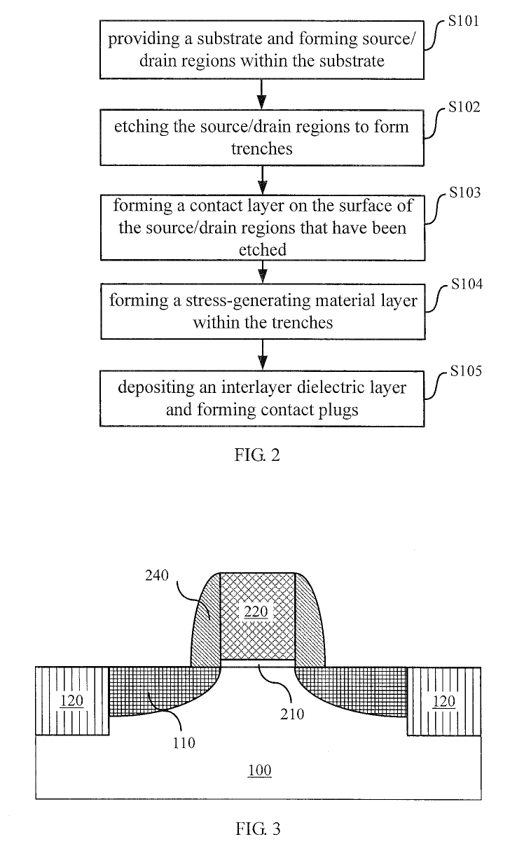

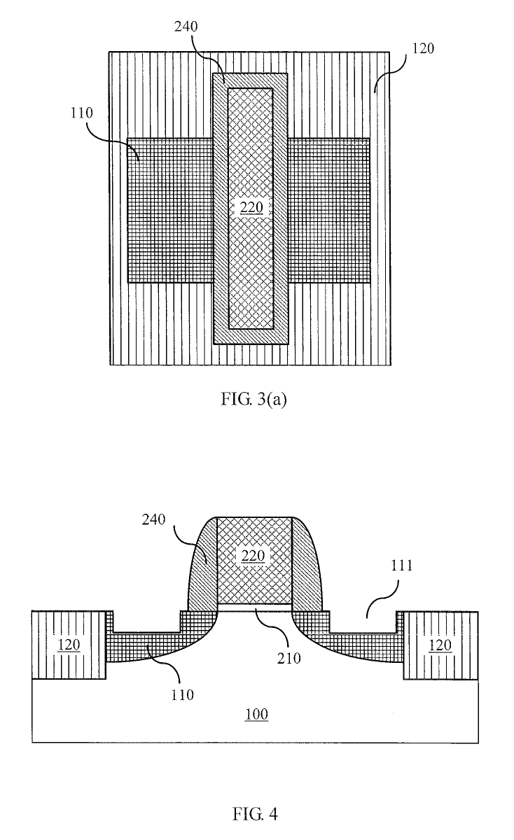

FIG. 2 illustrates a diagram of a method for manufacturing a semiconductor structure according to the present invention; FIG. 3 to FIG. 12 illustrate respectively cross-sectional views of a semiconductor structure manufactured at respective stages according to an embodiment of the method for manufacturing a semiconductor structure as illustrated in FIG. 2; and FIG. 3(a) to FIG. 12(a) illustrate top views of the semiconductor structure at respective manufacturing stages as shown in FIG. 3 to FIG. 12. The semiconductor structure at respective manufacturing stages can be illustrated much clearer with cross-sectional views of the semiconductor structure as shown in FIG. 3 to FIG. 12 in combination with top views of the semiconductor structure as shown in FIG. 3(a) to FIG. 12(a). Here below, the method for manufacturing a semiconductor structure as shown in FIG. 2 is to be delineated in conjunction with FIG. 3 to FIG. 12 and FIG. 3(a) to FIG. 12(a). However, it is noteworthy that the appended drawings for embodiments of the present invention are provided for purposes of illustration, and therefore, are not necessarily drawn to scale.

With reference to FIG. 2, FIG. 3 and FIG. 3(a), at step 5101, a substrate 100 is provided. A gate stack is formed on the substrate 100, and then source/drain regions 110 are formed within the substrate 100.

In the present embodiment, the substrate 100 includes Si substrate (e.g. wafer). According to design requirements in the prior art (e.g. a P-type substrate or an N-type substrate), the substrate 100 may be of various doping configurations. The substrate 100 in other embodiments may further include other basic semiconductors, for example, germanium. Alternatively, the substrate 100 may include a compound semiconductor, such as SiC, GaAs, InAs or InP. Alternatively, the substrate 100 may otherwise be silicon-on-insulator (SOI). Particularly, an isolation region may be formed in the substrate 100, for example, a shallow trench isolation (STI) structure 120, for purposes of electrically isolating continuous semiconductor structures.

A gate stack has to be formed before formation of source/drain regions 110. The gate stack, which is formed on the substrate 100, comprises a gate dielectric layer 210 and a metal gate 220. At formation of the gate stack, the gate dielectric layer 210 is formed on the substrate 100, wherein the material for the gate dielectric layer 210 may be any one selected from a group consisting of SiO₂, Si₃N₄ and combinations thereof, or may be a high K dielectric such as any one selected from a group consisting of HfO₂, HfSiO, HfSiON, HfTaO, HfSiO, HfZrO, Al₂O₃, La₂O₃, ZrO₂, LaAlO and combinations thereof. Next, the metal gate 220 is formed on the gate dielectric layer 210 by means of depositing any one selected from a group consisting of TaC, TiN, TaTbN, TaErN, TaYbN, TaSiN, HfSiN, MoSiN, RuTaₓ, NiTaₓ and combinations thereof. Particularly, sidewall spacers 240 may be formed on sidewalls of the gate stack by depositing-etching process for purposes of isolating the gate stack. The sidewall spacers 240 may be formed with any one selected from a group consisting of Si₃N₄, SiO₂, Si₂N₂O, SiC and combinations thereof, and/or other materials as appropriate. The sidewall spacers 240 may be a multi-layer structure. In other embodiments, the gate stack may comprise a gate dielectric layer and a dummy gate, wherein the dummy gate may be formed on the gate dielectric layer by depositing, for example, Poly-Si, Poly-SiGe, amorphous Si and/or oxides. In subsequent gate replacement steps, the dummy gate is removed and then a metal gate is formed.

Next, source/drain regions 110 may be formed by implanting P-type or N-type dopants/impurities into the substrate. For example, with respect to PMOS, the source/drain regions 110 may be P-type doped SiGe. And with respect to NMOS, the source/drain regions 110 may be N-type doped Si. The source/drain regions 110 may be formed by means of processes including lithography, ion implantation, diffusion and/or other processes as appropriate. Then, the semiconductor structure is annealed so as to activate dopants in the source/drain regions 110. The annealing process includes rapid annealing, spike annealing and other processes as appropriate. In another embodiment, source/drain regions 110 may be raised source/drain structures formed by means of selective epitaxial growth, and the top of the epitaxial portion is higher than the bottom of the gate stack (herein, the term “bottom of the gate stack” indicates the boundary of the gate stack and the semiconductor substrate 100).

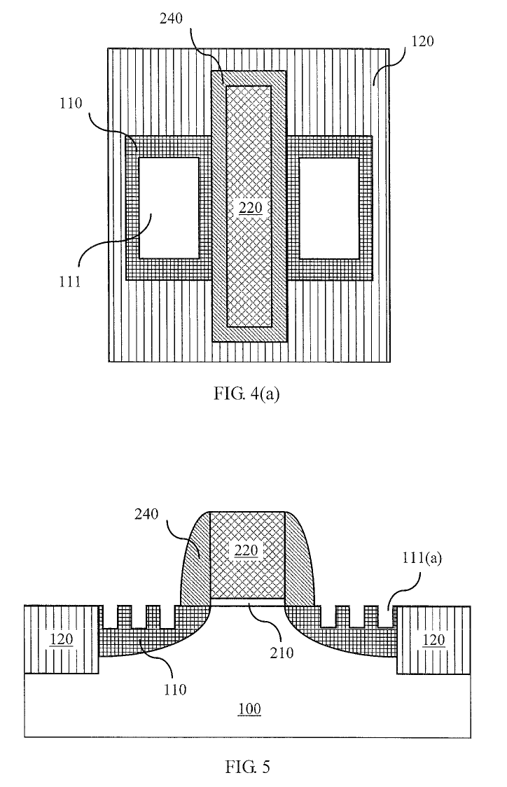

With reference to FIG. 2, FIG. 4 and FIG. 4(a), at step S102, the source/drain regions 110 are etched to form trenches. Specifically, the source/drain regions 110 may be etched by wet etching and/or dry etching to form hole-shaped trenches 111 with bottom and sidewalls. As compared to the source/drain regions 110 before etching, the source/drain regions 110 after etching have larger exposed regions, which accordingly increases the area for forming a contact layer in subsequent steps and effectively reduces contact resistance between the contact layer and source/drain regions 110. The wet etching process includes use of TMAH, KOH or other etching solutions as appropriate, while the dry etching process includes use of SF₆, HBr, HI, Cl, Ar, He and combinations thereof, and/or other materials as appropriate.

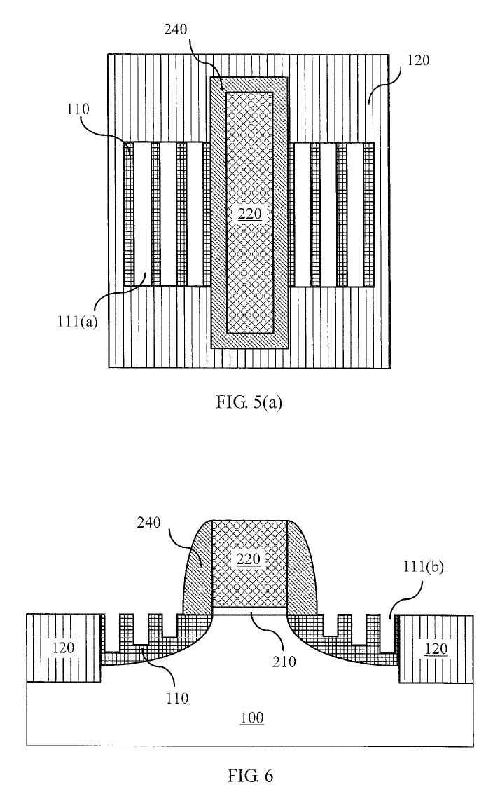

Preferably, it is also applicable to form a plurality of linear trenches 111(a) at the source/drain regions 110 with self-assembly block copolymer, for purposes of further increasing exposed regions at the source/drain regions 110, as shown in FIG. 5 and FIG. 5(a). Steps for forming a plurality of linear trenches 111(a) at the source/drain regions 110 with self-assembly block copolymer are described as follows: first, forming a layer of self-assembly block copolymer on the substrate 100, wherein the layer of self-assembly block copolymer comprises a first block copolymer composition A and a second block copolymer composition B that do not fuse into each other; next, implementing annealing treatment to the semiconductor structure to establish micro-phase isolation between the first block copolymer composition A and the second block copolymer composition B, so as to form a pattern layer, which comprises a plurality of linear structures and functions as a hard mask, on the substrate 100; selectively removing the first block copolymer composition A or the second block copolymer composition B, such that remaining block copolymer composition would constitute periodically a plurality of concavo-convex patterns; next, selectively etching the substrate 100 with the concavo-convex patterns as masks to form periodical linear trenches 111(a) within the source/drain regions 110; and finally, removing the concavo-convex patterns that have functioned as masks. The block copolymer is preferably linear di-block copolymer with A-B molecular type, which may be any one selected from a group consisting of PS-b-PMMA, PEO-b-PI, PEO-b-PBD, PEO-b-PS, PEO-b-PMMA, PEO-b-PEE, PS-b-PVP, PS-b-PI, PS-b-PBD, PS-b-PFS, PBD-b-PVP and PI-b-PMMA.

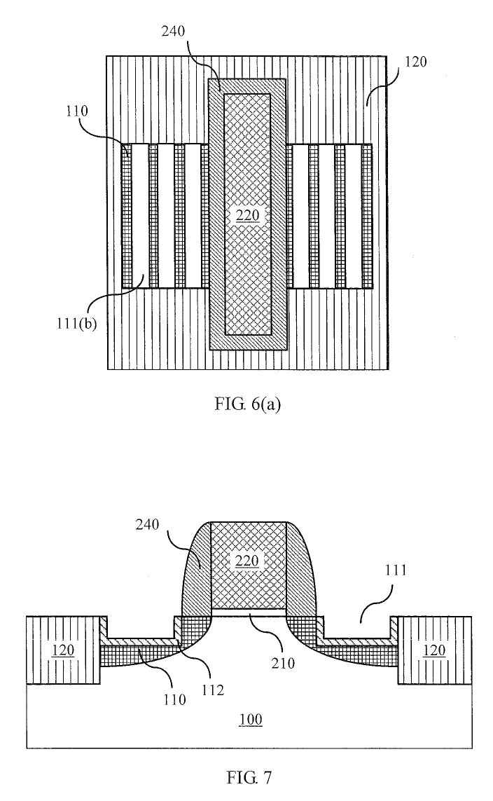

In other embodiments, trenches are not limited to hole-shaped trenches 111 or periodically linear trenches 111(a), but may be in any other shapes as appropriate, for example, the parallel linear trenches 111(b) with gradually increasing depth with respect to the shape the source/drain regions, as shown in FIG. 6 and FIG. 6(a).

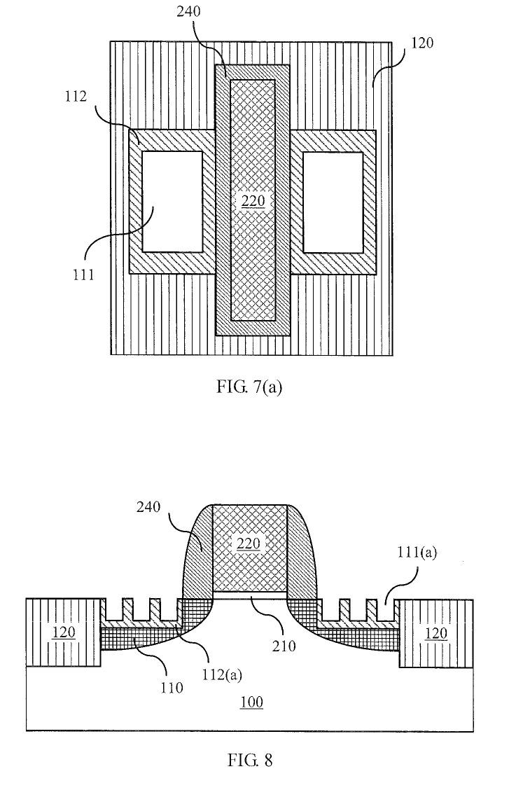

With reference to FIG. 2, FIG. 7 and FIG. 7(a), at step S103, a contact layer 112 is formed on the surface of the source/drain regions 110 after etching. In the present embodiment, the substrate 100 is Si substrate. Accordingly, the contact layer formed on the surface of the source/drain regions 110 after etching is a metal silicide layer. Here below, the contact layer is to be referred to as metal silicide layer.

Firstly, a metal layer is deposited to cover the source/drain regions 110 with hole-shaped trenches 111 and the gate stack; next, the semiconductor structure is annealed such that the metal layer reacts with Si in the source/drain regions 110; then a metal silicide layer 112 is formed on the surface of the source/drain regions 110 after annealing; and finally, portions of the metal layer which does not react to form the metal silicide layer are removed by means of selective etching

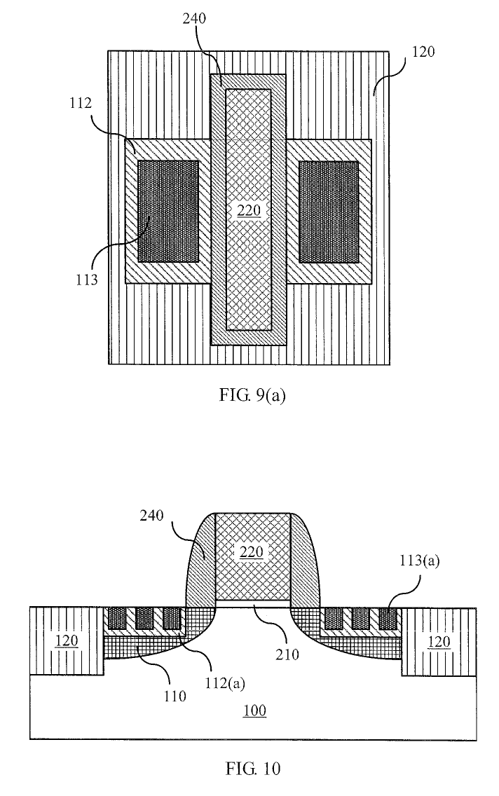

With reference to FIG. 2, FIG. 9 and FIG. 9(a), at step S104, a stress material layer is foamed inside the trenches. Specifically, in order to form a stress material layer only inside the trenches at the source/drain regions 110, it is applicable to form a stress material layer 113 inside the hole-shaped trenches 111 by means of, for example, selective atomic layer deposition (ALD). The stress material layer 113 is located on the metal silicide layer 112. The material for the stress material layer 113 may have preferably good conductivity, for example, a metal material capable of inducing stress. Different stress material layer may be formed regarding to different types of semiconductor structures. With respect to P-type semiconductor structures, the material for the stress material layer preferably includes any one selected from a group consisting of Ta, Zr and combinations thereof, which has good conductivity and is capable of applying compressive stress into channels between source and drain, thereby improving hole mobility within channels. With respect to N-type semiconductor structures, the material for the stress material layer preferably includes any one selected from a group consisting of Zr, Cr, Al and combinations thereof, which has good conductivity and is capable of applying tensile stress into channels between source and drain, thereby improving electron mobility within channels.

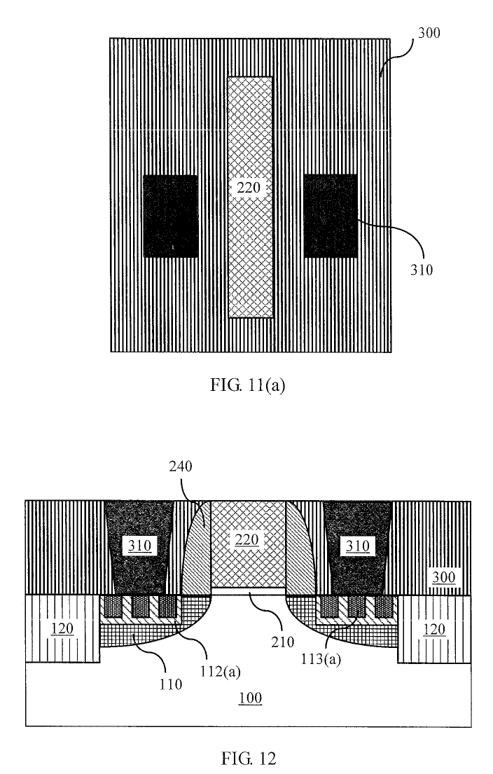

With FIG. 2, FIG. 11 and FIG. 11(a), at step S105, an interlayer dielectric layer 300 is deposited to form contact plugs.

The interlayer dielectric layer 300 is deposited to cover the substrate 100 and the gate stacks. The interlayer dielectric layer 300 may be formed by means of Chemical Vapor Deposition (CVD), High-Density Plasma CVD, spin coating and/or other processes as appropriate. The material for the interlayer dielectric layer 300 may be any one selected from a group consisting of USG, doped USG (e.g. FSG, BSG, PSG, BPSG), low-k dielectric materials (e.g. black diamond, coral), and combinations thereof. The interlayer dielectric layer 300 may be a multi-layer structure.

Next, the interlayer dielectric layer 300 is etched by lithography, dry etching or wet etching till the stress material layer 113 is exposed to form contact holes. Then, contact metal 310 is filled into the contact holes to form contact plugs, whose bottoms are electrically connected to the stress material layer 113. The contact metal may be W, Cu, TiAl, Al or alloy.

After formation of the contact plugs, the contact plugs are planarized by Chemical-Mechanical Polish (CMP), such that the upper surface of the contact plugs becomes flushed with the upper surface of the metal gate 220 (herein, the term “flush with” means that the difference between heights of two objects is in the permitted range of technical tolerance).

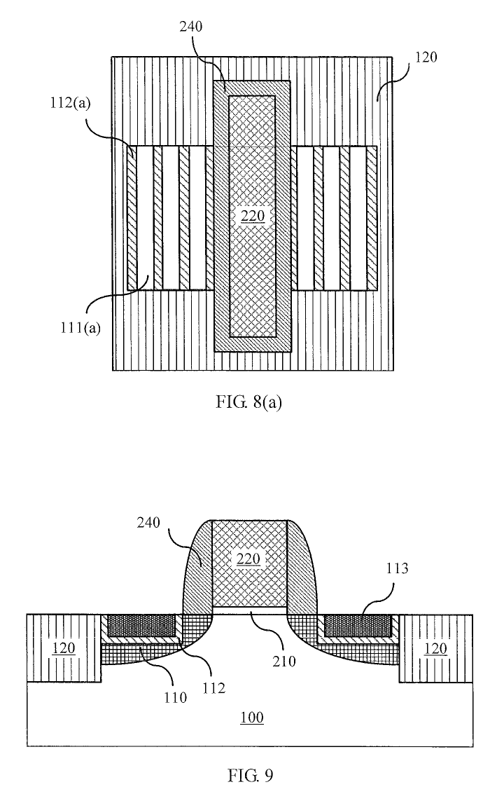

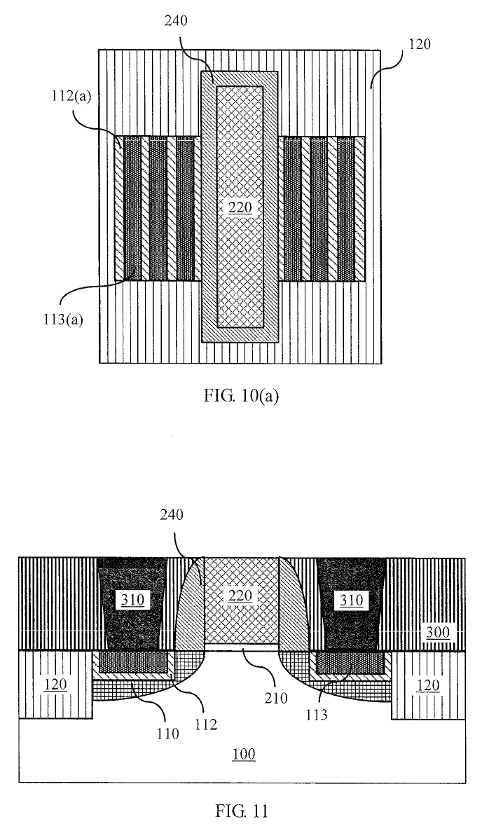

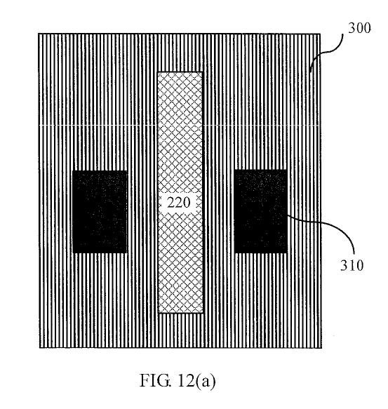

With reference to FIG. 8, FIG. 10, FIG. 12, FIG. 8(a), FIG. 10(a) and FIG. 12(a), for a semiconductor structure with a plurality of linear trenches 111(a) formed after the source/drain regions 110 have been etched, a metal silicide layer 112(a) is formed on the surface of the plurality of linear trenches 111(a) by the same aforementioned technical means; then, a stress material layer 113(a) is formed inside the plurality of linear trenches 111(a); and finally, an interlayer dielectric layer 300 is deposited and contact plugs are formed, wherein bottoms of the contact plugs are electrically connected to the stress material layer 113(a). Details of formation are omitted here in order not to obscure.

Then, manufacturing of the semiconductor structure is finished according to conventional semiconductor manufacturing processes.

After completion of aforesaid steps, the metal silicide layer is formed on the surface of the source/drain regions 110 that have been etched. Because the exposed area of the source/drain regions 110 after etching is larger than the exposed area of the source/drain regions 110 before etching, it can effectively increase the contact area between the metal silicide layer and the source/drain regions 110, which accordingly reduces contact resistance between the metal silicide layer and the source/drain regions 110 and enhances performance of the semiconductor structure. Additionally, owing to presence of the stress material layer formed by filling a stress material into the trenches formed at the source/drain regions 110 that have been etched, it is capable of applying tensile stress or compressive stress in channels between source and drain, which accordingly enhances carrier mobility within channels and further improves performance of the semiconductor structure.

With reference to FIG. 11 and FIG. 11(a), the present invention further provides a semiconductor structure, which comprises a substrate 100, a gate stack, source/drain regions 110, a metal silicide layer 112, an interlayer dielectric layer 300 and contact plugs. The gate stack, which is formed on the substrate 100, comprises a gate dielectric layer 210 and a metal gate 220; the source/drain regions 110 are formed respectively within the substrate 100 on each side of gate stack; the metal silicide layer 112 is located on the surface of the source/drain regions 110; the interlayer dielectric layer 300 covers the source/drain regions 110 and the gate stack; hole-shaped trenches 111 are formed in the source/drain regions 110; and a stress material layer 113 is embedded into the hole-shaped trenches 111 at the source/drain regions 110 (as shown in FIG. 7) and is formed above the metal silicide layer 112. With respect to a P-type semiconductor substrate, the material for the stress material layer 113 preferably includes any one selected from a group consisting of Ta, Zr and combinations thereof, which has good conductivity and is capable of applying compressive stress into channels between source and drain, and thereby enhancing hole mobility within channels. With respect to an N-type semiconductor substrate, the material for the stress material layer 113 preferably includes any one selected from a group consisting of Zr, Cr, Al and combinations thereof, which has good conductivity and is capable of applying tensile stress into channels between source and drain, and thereby enhancing electron mobility within channels. The contact plugs comprise contact metal 310 embedded within the interlayer dielectric layer 300, and bottoms of the contact plugs are electrically connected to the stress material layer 113.

Preferably, trenches at the source/drain regions 110 are not limited to hole-shaped trenches 111, but may be a plurality of linear trenches 111(a) (as shown in FIG. 8). A metal silicide layer 112(a) is formed on the surface of the plurality of linear trenches 111(a), and a stress material layer 113(a) is embedded into the plurality of linear trenches 111(a), as shown in FIG. 12 and FIG. 12(a). As shown in the drawings, the plurality of linear trenches 111(a) have larger surface area as compared to hole-shaped trenches 111, which accordingly further increases the contact area between the metal silicide layer 112(a) and the source/drain regions 110, reduces effectively contact resistance between the metal silicide layer 112(a) and the source/drain regions 110, and improves performance of the semiconductor structure. However, in other embodiments, trenches at the source/drain regions 110 may be in other shapes as appropriate.

Optionally, source/drain regions 110 may be raised source/drain structures formed by a selective epitaxial growing method, wherein the top of epitaxial portions thereof are higher than the bottom of the gate stack.

Since structural constitution, materials and formation methods of respective parts of the semiconductor structure in respective embodiments may be the same as embodiments of the aforesaid method for manufacturing a semiconductor structure, and thus they are not described here in detail in order not to obscure. Although the exemplary embodiments and their advantages have been described in detail, it should be understood that various alternations, substitutions and modifications may be made to the embodiments without departing from the spirit of the present invention and the scope as defined by the appended claims. For other examples, it may be easily recognized by a person of ordinary skill in the art that the order of processing steps may be changed without departing from the scope of the present invention.

In addition, the scope to which the present invention is applied is not limited to the process, mechanism, manufacture, material composition, means, methods and steps described in the specific embodiments in the specification. According to the disclosure of the present invention, a person of ordinary skill in the art would readily appreciate from the disclosure of the present invention that the process, mechanism, manufacture, material composition, means, methods and steps currently existing or to be developed in future, which perform substantially the same functions or achieve substantially the same as that in the corresponding embodiments described in the present invention, may be applied according to the present invention. Therefore, it is intended that the scope of the appended claims of the present invention includes these process, mechanism, manufacture, material composition, means, methods or steps.

1. A method for manufacturing a semiconductor structure, comprising:
a) providing a substrate, forming a gate stack on the substrate and forming source/drain regions within the substrate;
b) etching the source/drain regions to form trenches;
c) forming a contact layer on a surface of the source/drain regions that have been etched;
d) forming a stress material layer within the trenches; and
e) depositing an interlayer dielectric layer and forming contact plugs in contact with the stress material.

2. The method of claim 1, wherein:
the trenches include hole-shaped trenches or a plurality of linear trenches.

3. The method of claim 2, wherein the plurality of linear trenches are formed by:
forming a pattern layer comprising a plurality of linear structures on the source/drain regions with a self-assembly block copolymer as a hard mask; and
etching the source/drain regions to form the plurality of linear trenches with the pattern layer as a mask.

4. The method of claim 1, wherein:
the stress material layer is formed within the trenches by means of selective atomic layer deposition.

5. The method of claim 1, wherein:
the stress material layer includes a conductive material used in an N-type semiconductor substrate for inducing tensile stress or a conductive material used in a P-type semiconductor substrate for inducing compressive stress.

6. The method of claim 5, wherein:
the material for inducing tensile stress includes any one selected from a group consisting of Zr, Cr, Al and combinations thereof.

7. The method of claim 5, wherein:
the material for inducing compressive stress includes any one selected from a group consisting of Ta, Zr and combinations thereof.

8. The method of claim 1, wherein the source/drain regions are raised source/drain regions.

9. The method of claim 3, wherein the self-assembly block copolymer is any one selected from a group consisting of PS-b-PMMA, PEO-b-PI, PEO-b-PBD, PEO-b-PS, PEO-b-PMMA, PEO-b-PEE, PS-b-PVP, PS-b-PI, PS-b-PBD, PS-b-PFS, PBD-b-PVP and PI-b-PMMA or combinations thereof.

10. A semiconductor structure, comprising a substrate, a gate stack, source/drain regions, a contact layer, an interlayer dielectric layer and contact plugs, wherein, the gate stack is formed on the substrate, the source/drain regions are formed respectively within the substrate on each side of gate stack, the contact layer is located on a surface of the source/drain regions, the interlayer dielectric layer covers the source/drain regions and the gate stack, and wherein:
a stress material layer is embedded into the source/drain regions and is formed on the contact layer; and the contact plugs are embedded into the interlayer dielectric layer and are electrically connected to the stress material layer.

11. The semiconductor structure of claim 10, wherein:
the stress material layer is embedded into trenches at the source/drain regions, and wherein the trenches include hole-shaped trenches or a plurality of linear trenches.

12. The semiconductor structure of claim 10, wherein:
the stress material layer includes a conductive material used in an N-type semiconductor substrate for inducing tensile stress or a conductive material used in a P-type semiconductor substrate for inducing compressive stress.

13. The semiconductor structure of claim 12, wherein:
the material for inducing tensile stress includes any one selected from a group consisting of Zr, Cr, Al or combinations thereof.

14. The semiconductor structure of claim 12, wherein:
the material for inducing compressive stress includes any one selected from a group consisting of Ta, Zr or combinations thereof.

15. The semiconductor structure of claim 10, wherein the source/drain regions are raised source/drain regions.

16. The method of claim 4, wherein:
the stress material layer includes a conductive material used in an N-type semiconductor substrate for inducing tensile stress or a conductive material used in a P-type semiconductor substrate for inducing compressive stress.
